(19) United States
(12) Patent Application Publication
(10) Pub. No.: US 2025/0115799 A1
(43) Pub. Date: Apr. 10, 2025

(54) Thermal Interface Materials with Soft Filler Dispersions

(71) Applicant: Henkel AG & Co. KGaA, Duesseldorf (DE)

(72) Inventors: Sanjay Misra, Chanhassen, MN (US); Matthew Anthony Henderson, Cannon Falls, MN (US); Radesh Jewram, Chanhassen, MN (US)

(21) Appl. No.: 18/984,217

(22) Filed: Dec. 17, 2024

Related U.S. Application Data
(63) Continuation of application No. PCT/US2023/025953, filed on Jun. 22, 2023.
(60) Provisional application No. 63/354,249, filed on Jun. 22, 2022.

(51) Int. Cl. C09K 5/06; C08K 9/06; F28F 13/00

(52) U.S. Cl. CPC C09K 5/066; C08K 9/06; C09K 5/063; F28F 13/00; C08K 2201/001; C08K 2201/005; F28F 2013/001

(57) ABSTRACT

A heat transfer assembly utilizes a thermal interface material in a thermal dissipation pathway between a heat-generating component and a heat dissipater. The thermal interface material is disposed in a gap along the thermal dissipation pathway between a first surface and a second surface, wherein the gap has a mean gap width. The thermal interface material includes a matrix material and a particulated metal filler dispersed in the metal matrix, wherein the particulated metal filler has a melting point temperature of between 0° C. and 100° C., and a mean particle size that is equal to or greater than the mean gap width of the gap.

### FIELD

The present invention relates to thermal interface materials generally, and more particularly to a gap-filling thermal interface material for transferring heat from the heat generator to a heat dissipator. The thermal interface material utilizes low-melting point metal filler that is dispersed in particulated form in a matrix material, such as an elastomeric polymer.

### BACKGROUND

Conventional thermal interface materials typically include polymeric matrices with dispersed thermally conductive particles that impart thermal conductivity to the bulk material. However, traditional thermal interface materials exhibit certain limitations in conductive performance due to the size exclusion at the boundaries of the interface material caused by hard filler particles. The exclusion zone near the interface is often polymer rich with a thickness approximately equal to the harmonic mean particle size of the thermally conductive particles. This exclusion layer exhibits low, polymer like thermal conductivity, and is an impediment to heat transfer. As thermal applications require reduced bond line thicknesses, the heat transfer impediment becomes more pronounced, leading to decreased effectiveness of conventional thermal interface materials.

An additional issue exhibited in conventional thermal materials is insufficient phonon transport due to poor conductive particle contact. Thermal energy is therefore too often scattered through the matrix, leading to reduced transport efficiencies.

It is therefore an object of the invention to reduce or eliminate the exclusion zones at both particle-particle and bulk material-thermal surface interfaces. To do so, the contact resistance between such interfaces is preferably reduced by employing soft filler particles that are capable of changing shape under the heat and pressure experienced in typical operating conditions. Through this approach, effective thermal conductivity may in fact increase with decreasing bond line thicknesses, which is opposite from the effect observed in conventional thermal interface materials with hard filler particles. Increased thermal conductivity with decreased bond line thicknesses arises from increased bridging across the interface thickness by soft conductive particles, and more coherent heat transfer within the bulk interface material.

### SUMMARY

By means of the present invention, thermal conductivity performance is improved for thermally conductive materials in thin bond line applications, such as gap fillers for gap sizes of less than 500 μm, and preferably less than 200 μm. In particular, thermal conductivity performance improves with decreasing bond line thickness. The thermal interface materials of the present invention are therefore disposed in a gap having a mean gap size separating the gap—defining thermal surfaces along a thermal dissipation pathway. The thermal interface materials of the present invention utilize particulated low melting point metal filler distributed in a matrix material, wherein the filler provides highly thermally conductive soft particles at typical operating temperatures exceeding room temperature.

The invention may be incorporated in a heat transfer assembly for transferring heat along a thermal dissipation pathway between a heat generating component and a heat dissipater, such as a heat sink or a heat spreader. A thermal interface material is applied to the heat transfer assembly gap, wherein the thermal interface material is tuned for the gap. In particular, the soft thermally conductive particles of the thermal interface material are specifically selected in a particle size range that spans the gap to enhance bridging and particle-particle contact. It has been discovered that a specific relationship of particle size to gap size achieves the observed conductivity performance improvement when the soft thermally conductive particles of the present invention are utilized.

In one embodiment, a heat transfer assembly includes a first surface and a second surface spaced from the first surface by a gap having a mean gap size. The first surface may be associated with a heat generating component, and the second surface may be associated with a heat dissipater. In one embodiment, the first surface forms a portion of the heat generating component, and the second surface forms a portion of the heat dissipater. The heat transfer assembly further includes a thermal interface material disposed in the gap and in contact with the first and second surfaces. The thermal interface material includes a matrix material and a particulated metal filler dispersed in the matrix material. The particulated metal filler has a melting point temperature of between 0° C. and 100° C., and a mean particle size that is greater than or equal to the mean gap size.

In some embodiments, the particulated metal filler may be present in the matrix material at a concentration of between 40% and 90% by volume. In some embodiments, the particulated metal filler may be present in the matrix material at a concentration of between 70% and 90% by volume. The particulated metal filler may be an alloy of one or more of gallium, indium, bismuth, tin, and zinc. In some embodiments, the particulated metal filler is an alloy of between 50-75% by weight gallium, 10-30% by weight indium, and 5-20% by weight tin.

In some embodiments, the particulated meal filler has a melting point temperature of between 0° C. and 20° C.

A hydrophobic surface active agent may be chemically bonded to a surface of the particulated metal filler to aid in shelf stability and to reduce environmental degradation. In some embodiments, the surface active agent may be selected from one or more of a silane and a titanate.

A weight ratio of the particulated metal filler to the matrix material may be between 20:1 and 60:1. In some embodiments, the weight ration of the particulated metal filler to the matrix material may be between 30:1 and 55:1.

The matrix material may include a polymer. In some embodiments, the matrix material includes a thermoplastic elastomer, to form a polymer matrix. In some embodiments, the polymer matrix may be formed from a fluid resin having a viscosity of between 200 cP and 1,000 cP at 25° C.

A mean particle size of the particulated metal filler may be between 100% and 150%

of the mean gap size. The mean gap size may, in some embodiments, be between 10 μm and 200 μm.

A mesh body may be disposed in the gap as a reinforcing member for the thermal interface material. In some embodiments, the mesh body may be embedded within the thermal interface material in the gap. The mesh body may comprise a metal or a graphite.

The first surface of the heat transfer assembly may be associated with a heat generating device, and the second surface of the heat transfer assembly may be associated with a heat dissipater. The heat dissipater may be a heat sink or a heat spreader.

In one embodiment, a heat transfer assembly defines a gap having a mean gap size that separates a first surface from a second surface. A method for forming the heat transfer assembly includes providing a thermal interface material having a matrix material and 40-90% by volume of a particulated metal filler dispersed in the matrix material. The particulated metal filler has a melting point temperature of between 0° C. and 100° C., and a mean particle size that is less than or equal to the mean gap size. The thermal interface is applied to at least one of the first and second surfaces. The method may further include contacting the thermal interface material to both of the first and second surfaces and arranging the first and second surfaces to be separated by the gap.

In some embodiments, the first surface may be associated with a heat generating device, and the second surface may be associated with a heat dissipator. In this arrangement, a thermal dissipation pathway extends from the first surface, through the thermal interface material, and to the second surface.

### BRIEF DESCRIPTION OF THE DRAWINGS

FIG. 1 is a schematic illustration of a heat transfer assembly of the present invention.

FIG. 2 is a schematic illustration of a heat transfer assembly of the present invention.

FIG. 3 is a schematic illustration of a portion of the heat transfer assembly illustrated in FIG. 2.

FIG. 4 is a flow diagram illustrating a method of forming a heat transfer assembly of the present invention.

### DETAILED DESCRIPTION

The heat transfer assemblies of the present invention may be employed in a wide variety of applications for dissipating excess thermal energy from the heat-generating electronic component. The heat transfer assemblies define a gap between a first surface and a second surface, wherein a thermally conductive material fills the gap along a thermal dissipation pathway. The thermally conductive material preferably exhibits a desired thermal conductivity of at least 1 W/m*K, and more preferably at least 3 W/m*K.

The thermally conductive material may be formed as a solid, semi-solid, or liquid mixture including a particulated metal filler dispersed in a matrix material. The particulated metal filler may have a low melting point temperature of between 0° C. and 100° C., and may be dispersed in solid or liquid form in the matrix material. In typical embodiments, at least the particulated metal filler is in a liquid state at operating conditions of the heat transfer assembly. In some embodiments, both of the particulated metal filler and the matrix material are in a liquid state at operating conditions of the heat transfer assembly. In some embodiments, both of the particulated metal filler and the matrix material are in a liquid state at room temperature, wherein the combination forms a liquid-liquid emulsion.

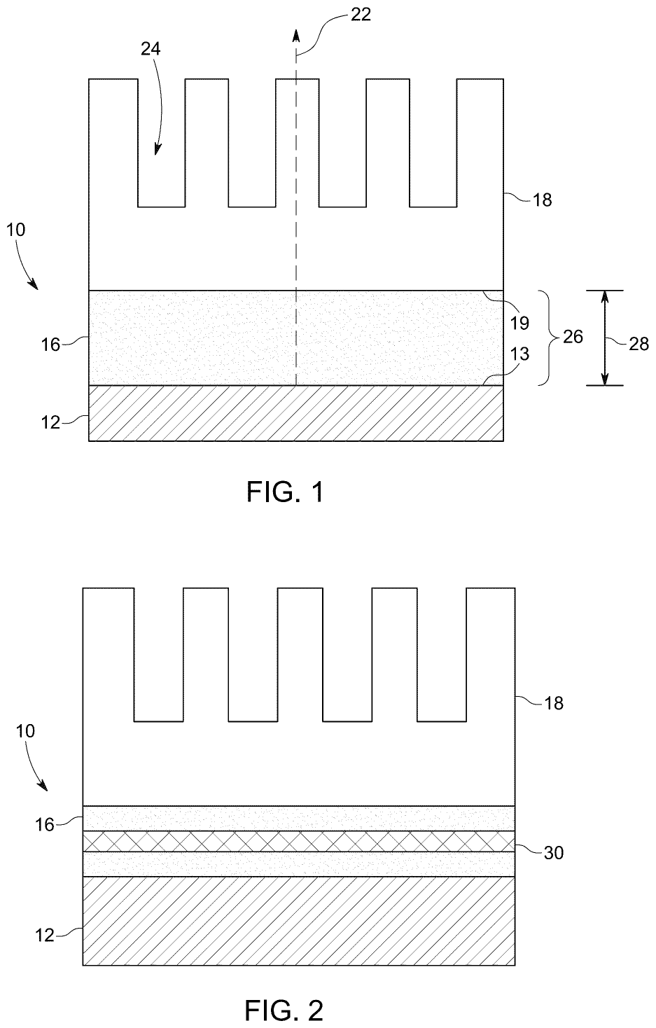

An example heat transfer assembly 10 incorporating a thermal interface material 20 is illustrated in FIG. 1. Heat transfer assembly 10 includes an electronic component 12 or a substrate to which may be mounted one or more heat-generating electronic components. Heat transfer assembly 10 further includes a heat dissipater 18 in the form of a heat sink or heat spreader. A first surface 13 is associated with electronic component 12, and a second surface 19 is associated with heat dissipater 18. First surface 13 may form a portion of electronic component 12 or may form a portion of a first body that is thermally coupled to electronic component 12. The first body may be separate from, connected to, or integrally formed with electronic component 12. Second surface 19 may form a portion of heat dissipater 18 or may form a portion of a second body that is thermally coupled to heat dissipater 18. The second body may be separate from, connected to, or integrally formed with heat dissipater 18.

Second surface 19 is spaced or separated from first surface 13 by a gap 26 having a mean gap width 28. For the purposes hereof, the term “mean gap width” is intended to be the mean distance between first and second surfaces 13, 19, as measured along a thermal dissipation pathway 22 from the heat-generating electronic component 12 and heat dissipater 18. Thermal interface material 16 is disposed in gap 26 along the thermal dissipation pathway 22, such that the mean gap width may be determined as the mean distance between first and second surfaces 13, 19 where thermal interface material 16 is disposed along thermal dissipation pathway 22 in gap 26. In some embodiments, thermal interface material 26 is disposed in gap 26 in contact with first and second surfaces 13, 19. In some embodiments, thermal interface material 16 substantially fills gap 26 along thermal dissipation pathway 22.

It is an aspect of the invention to provide an effective thermal dissipation pathway at small bond lines or mean gap widths. As described above, conventional thermally conductive materials have limited effectiveness with very small mean gap widths, such as less than 500 μm, preferably less than 200 μm, and particularly between 10 μm and 200 μm. The heat transfer assemblies of the present invention are specifically adapted to provide high thermal conductivity with low mean gap widths of less than 500 μm.

Heat transfer assembly 10 is arranged to dissipate thermal energy generated by electronic component 12 (and/or an array of electronic components 12) by providing a highly thermally conductive path from electronic component 12 to a heat-absorbing fluid media 24 in contact with heat dissipater 18. In typical applications, fluid media 24 may be a gas, such as air, that may be motivated by an air mover to absorb thermal energy from heat dissipater 18. Heat transfer assembly 10 is an example arrangement that may be modified as appropriate to accommodate a variety of electronic applications, such as data processors, data memory, communication boards, antennae, and the like. Such devices may be utilized in computing devices, communication devices, and peripherals therefor. In a particular example embodiment, heat transfer assembly 10 may be employed to support various functions in a cellular communication device.

A substrate may serve one or more of a variety of functions in addition to being a support for one or more electronic components 12. For example, a substrate may be a circuit board, such as a printed circuit board with electrically conductive traces for electrically connecting electronic components 12 as needed in the assembly. The substrate may also or instead by a heat spreader, fabricated with at least a layer of thermally conductive material. In operation, electronic components 12 generated significant excess thermal energy which must be dissipated in order to maintain optimal performance. Electronic components 12 may be any of a variety of elements useful in an electronic process, and may include, for example, integrated circuits, resistors, transistors, capacitors, inductors, and diodes.

Thermal interface material 16 provides a thermally conductive bridge between first and second surfaces 13, 19 along thermal dissipation pathway 22. Thermal interface material 16 includes a matrix material and a particulated metal filler dispersed in the matrix material.

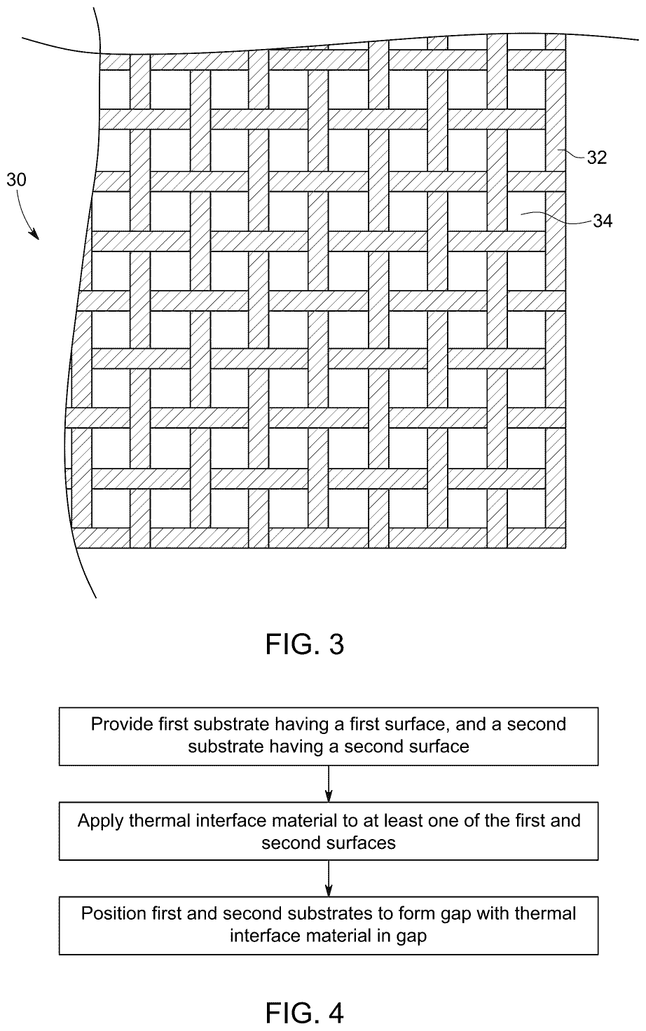

In some embodiments, as illustrated in FIG. 2, a mesh body 30 is disposed in gap 26 to enhance the mechanical stability of thermal interface material 16 in gap 26. As shown in FIG. 3, Mesh body 30 may be a woven or non-woven structure of interlaid, adjacent, or intersecting fibers or wires 32 that define open interstices 34 of mesh body 30. Thermal interface material 16 may be disposed on fibers or wires 32, and in some embodiments may partially or wholly fill interstices 34 of mesh body 30. In some embodiments, mesh body 30 may be embedded in thermal interface material 16.

Mesh body 30 is preferably thermally conductive to minimize or avoid impediments to heat transfer through gap 26. Although a wide variety of thermally conductive materials may be utilized for mesh body 30, example materials include a metal or graphite.

Heat transfer assembly 10 may be assembled, as set forth in FIG. 4, to define gap 30 having a mean gap width 28 that separates first surface 13 from second surface 19 by applying thermal interface material 16 to at least one of first and second surfaces 13, 19, and positioning first and second surfaces 13, 19 so that thermal interface material 16 is disposed therebetween, and so that first and second surfaces are spaced apart by gap 26 with mean gap width 28. In some embodiments, thermal interface material 16 is contacted to both of first and second surfaces 13, 19.

### Matrix Material

The matrix material may act as a binder to hold the composition together and to prevent outflow in operation. Typical matrix materials useful in the present invention may be thermoplastic or thermoset polymers that may be blended with the particulated metal filler to form the thermal interface material, most typically in the form of a liquid-liquid emulsion. Example polymers for forming the matrix include elastomers comprising one or more of a silicone, an acrylic, a natural rubber, a synthetic rubber, or other appropriate elastomeric materials. Example viscoelastic materials including alkenylarene copolymers, urethanes, polyurethanes, rubbers, acrylics, silicones, polyesters, and vinyls. Still further example polymer matrix materials include paraffin, microwax, silicone waxes, silicones, epoxies, and trimellitate.

In some embodiments, the matrix material undergoes a phase change at or slightly below the device operating temperature range, and preferably at or slightly below the melting point temperature of the particulated metal filler. For the purposes hereof, the term “phase change” means softening from a solid or semi-solid material to a viscous, grease-like, flowable, or liquid material. In some embodiments, the matrix material undergoes a phase change at a temperature of about 10° C. lower than the melting point temperature of the particulated metal filler.

In some embodiments, the matrix material includes a thermoplastic elastomer that is formed from a fluid resin having a viscosity of between 200 and 1000 cP at 25° C.

An example silicone polymer includes an organosiloxane having the structural formula:

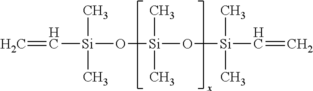

wherein “x” represents an integer ranging from between 1 and 1,000. In some embodiments, the matrix material may be prepared as a reaction product of the organosiloxane together with a chain extender/cross-linker such as a hydride-functional polydimethyl siloxane having the structural formula:

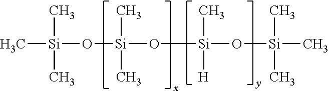

wherein “x” and “y” each represent an integer having a value of between 1 and 1,000.

### Metal Filler

The metal material or materials forming the metal filler may exhibit a melting point temperature of between 0° C. and 100° C., and preferably below an operating temperature of a heat generating device to which the heat transfer apparatus of the present invention is thermally coupled. In some embodiments, the metal filler may exhibit a melting point temperature of between 0° C. and 75° C. In some embodiments, the metal filler may exhibit a melting point temperature of between 0° C. and 60° C. In some embodiments, the metal filler may exhibit a melting point temperature of between 0° C. and 50° C. In some embodiments, the metal filler may exhibit a melting point temperature of between 0° C. and 20° C.

Although the metal filler may comprise a single metal material, typical metal fillers useful in the thermal interface materials of the present invention include alloys of two or more metal materials such as gallium, indium, bismuth, tin, and zinc. An example alloy metal filler of the present invention comprises 50-75% by weight gallium, 10-30% by weight indium, and 5-20% by weight tin. A particular example alloy metal filler of the present invention comprises 66% by weight gallium, 20.5% by weight indium, and 13.5% by weight tin, with a melting point of 10.5° C. Other alloy blends, however, are contemplated for use as the metal filler in the thermal interface material of the present invention.

The metal filler may comprise between 40% and 95% by volume of the thermal interface material. In some embodiments, the metal filler may comprise between 50% and 90% by volume of the thermal interface material. In some embodiments, the metal filler may comprise between 60% and 90% by volume of the thermal interface material. In some embodiments, the metal filler may comprise between 70% and 90% by volume of the thermal interface material

The metal filler may be present in the thermal interface material in a weight ratio of the metal filler to the matrix material of between 20:1 and 60:1. In some embodiments, the metal filler may be present in the thermal interface material in a weight ratio of the metal filler to the matrix material of between 30:1 and 55:1.

The metal filler may be subjected to a sizing operation to particulate the metal/alloy material into a desired particle size distribution, including monodisperse, polydisperse, gaussian, multi-modal, and the like. The sizing operation may perform upon the metal filler alone, or with the metal filler mixed with the matrix material. In some embodiments, the particulating and/or sizing operation may be performed by a high shear mixer. An example approach includes blending the metal filler with the matrix material in a high shear mixer until the metal filler becomes thoroughly dispersed in the polymer, at which time it may be formed into the configuration desired for the thermal interface. The metal filler and matrix material may be blended in a liquid phase, a solid phase, or a combination of liquid and solid phases. In the case of mixing the metal filler and matrix material when both components are in a liquid phase, the metal filler may be particulated into discrete small droplets and dispersed in the matrix material as an emulsion. In some embodiments, the thermal interface material includes particulated metal filler in a maximum amount that nonetheless remains stable in an emulsion or dispersion with the matrix material by remaining encapsulated by the matrix material and not separating out from the matrix material.

Particle size of the particulated metal filler is preferably controlled to achieve a particle size distribution with a mean particle size that is associative with a mean gap width. In some embodiments, particle size may be controlled with shear imparted upon the metal filler. Particulated metal filler with a desired particle size distribution and mean particle size may also be obtained from commercial sources. An example process involves placing a mixture of metal filler and matrix material under shear force until a dispersion or emulsion is formed with desired particulated metal filler mean particle size. For the purposes hereof, the mean particle size of the particulated metal filler may be measured with the particulated metal filler in a dispersed state, encapsulated by the matrix material. Mean particle size may be ascertained by various techniques, including volume, area, or weight-based measurement techniques.

As noted above, the particle size of the particulated metal filler is preferably related to the mean gap width. In some embodiments a mean particle size of the particulated metal filler is greater than or equal to the mean gap width. Applicant has discovered that high thermal conductivity/low thermal impedance may be achieved in a system utilizing soft metal thermally conductive filler that can bridge first and second surfaces forming a gap. The soft metal material, alone, is not suitable as a thermal interface material due to the relatively high surface tension of metal materials that limit the extent of wetting of the first and second thermal surfaces. Thus, the soft metal material may be combined with a matrix material exhibiting a suitably low surface tension to wet the first and second thermal surfaces of the heat transfer assembly while leveraging the high thermal conductivity of the soft metal material. The mean particle size of the particulated metal filler is therefore at least the size of the mean gap width in order to maximize thermal bridging by the metal filler between the first and second thermal surfaces of the heat transfer assembly. Metal filler particles that are larger than the mean gap width may be deformed due to their softness. In some embodiments, the metal filler particles may be in liquid or semi-liquid form at ambient room temperatures, which permits deformation between the first and second thermal surfaces in construction of the heat transfer assembly. In other embodiments, the thermal interface material may be applied to surface and sandwiched between the surface and another surface under pressure and elevated temperature. The elevated temperature may be used to soften or liquefy metal filler particles having a melting or transition point temperature exceeding ambient room temperatures.

Metal filler particles with a mean particle size greatly exceeding the mean gap width, however, can impede construction of the heat transfer assembly due to the mechanical resistance to compression from the metal particles. In some embodiments, the mean particle size of the particulated metal filler is between 100% and 500% of the mean gap width. In some embodiments, the mean particle size of the particulated metal filler is between 100% and 200% of the mean gap width. In some embodiments, the mean particle size of the particulated metal filler is between 100% and 150% of the mean gap width. In some embodiments, the mean particle size of the particulated metal filler is between 150% and 500% of the mean gap width. In some embodiments, the mean particle size of the particulated metal filler is between 150% and 300% of the mean gap width.

The mean gap width is preferably small to maximize heat transfer through the heat transfer assembly. In some embodiments, the mean gap width is less than 500μm. In some embodiments, the mean gap width is less than 200 μm. In some embodiments, the mean gap width is between 10 μm and 200 μm.

### Surface Active Agent

Various surface active agents may be employed to improve the rheology of the thermal interface material, as well as to improve stability of the particulated metal filler dispersion in the matrix material. In some embodiments, one or more surface active agents may be used to establish a hydrophobic barrier near the surface of the particulated metal filler. The hydrophobic surface active agent or agents may, in some embodiments, be chemically bonded to the particulated metal filler. Surface treatments with surface active agents that work well for improving rheology as well as stability of the dispersion, especially against moisture, include alkyl functional silanes, such as alkyl-tri-alkoxy silanes including octyl triethoxysilane, methyl trimethoxysilane, hexadecyltrimethoxysilane, and phenyltriethoxysilane. These silanes bind to oxides on the surface of the metal particles, creating a durable hydrophobic barrier. Additionally, these silanes compatibilize the metal particles with the matrix material and reduce particle aggregation by reducing surface energy. Alternatively, or additionally, titanates or ziroconates may be used as surface active agents.

Surface active agents may be used in the thermal interface materials of the present invention in a concentration range of between 0.01% and 10% by weight of the total composition. In some embodiments, a surface active agent may be present in the thermal interface materials of the present invention in a concentration range of between 0.05% and 5% by weight of the total composition. In some embodiments, a surface active agent may be present in the thermal interface materials of the present invention in a concentration range of between 0.1 and 1% by weight of the total composition. In some embodiments, a surface active agent may be present in the thermal interface materials of the present invention in a concentration range of between 0.1% and 0.5% by weight of the total composition. In some embodiments, a surface active agent may be present in the thermal interface materials of the present invention in a concentration range of between 0.2% and 0.4% by weight of the total composition.

### Optional Additives

In accordance with some embodiments of the present invention, the compositions described herein may further comprise one or more flow additives, adhesion promoters, rheology modifiers, toughening agents, fluxing agents, film flexibilizers, phenol-novolac hardeners, curing agents (catalysts, promoters, initiators, etc.), and the like, as well as mixtures of any two or more thereof.

As used herein, the term “flow additives” refers to compounds which modify the viscosity of the formulation to which they are introduced.

As used herein, the term “adhesion promoters” refers to compounds which enhance the adhesive properties of the formulation to which they are introduced.

As used herein, the term “rheology modifiers” refers to additives which modify one or more physical properties of the formulation to which they are introduced.

As used herein, the term “toughening agents” refers to additives which enhance the impact resistance of the formulation to which they are introduced.

As used herein, the term “fluxing agents” refers to reducing agents which prevent oxides from forming on the surface of the metal filler.

As used herein, the term “film flexibilizers” refers to agents which impart flexibility to the films prepared from formulations containing same.

As used herein, the term “curing agents” refers to reactive agents which participate in or promote the curing of monomeric, oligomeric or polymeric materials.

### EXAMPLES

The following examples demonstrate thermal impedance and effective thermal conductivity for various thermal interface materials within various mean gap widths of a heat transfer assembly. Thermal testing was performed pursuant to the ASTM D5470 thermal interface material test.

### Example 1

The following Table 1A describes the composition of the thermal interface material:

TABLE 1A

| | 80 vol % metal | | |
|---|---|---|---|
| | filler | | |
| Thermal Interface | Formulation | Concentration | |
| Material | (phr) | (wt %) | Mass (g) |
| Silicone Polymer Matrix | 90 | 3.2 | 3.88 |
| Trimethoxy(octyl)silane | 10 | 0.4 | 0.43 |
| Particulated Metal Filler | 2680 | 96.4 | 115.68 |

The matrix material was formed from a silicone polymer having a viscosity of 500 cP at 25° C. The particulated metal filler was an alloy of 66% by weight gallium, 20.5% by weight indium, and 13.5% by weight tin. The particulated metal filler had a mean particle size of 200 um and a melting point temperature of 10.5° C. The trimethoxy (octyl) silane was used as a surface modifying agent for providing hydrophobicity to the particulated metal filler.

The following Table 1B sets forth thermal impedance and effective thermal conductivity values of a heat transfer assembly using the thermal interface material to fill different mean gap widths:

TABLE 1B

| | Thermal Impedance | Effective Thermal |
|---|---|---|
| Gap (μm) | (° C.-cm²/W) | Conductivity (W/m*K) |
| 212 | 0.590 | 3.59 |
| 112 | 0.333 | 3.35 |
| 67 | 0.138 | 4.93 |
| 44 | 0.064 | 6.83 |

### Example 2

The following Table 2A describes the composition of the thermal interface material:

TABLE 2A

| | 85 vol % metal | | |
|---|---|---|---|
| | filler | | |
| Thermal Interface | Formulation | Concentration | |
| Material | (phr) | (wt %) | Mass (g) |
| Silicone Polymer Matrix | 90 | 2.3 | 2.77 |
| Trimethoxy(octyl)silane | 10 | 0.3 | 0.31 |
| Particulated Metal Filler | 3797 | 97.4 | 116.92 |

The matrix material was formed from a silicone polymer having a viscosity of 500 cP at 25° C. The particulated metal filler was an alloy of 66% by weight gallium, 20.5% by weight indium, and 13.5% by weight tin. The particulated metal filler had a mean particle size of 80 μm and a melting point temperature of 10.5° C. The trimethoxy (octyl) silane was used as a surface modifying agent for providing hydrophobicity to the particulated metal filler.

The following Table 2B sets forth thermal impedance and effective thermal conductivity values of a heat transfer assembly using the thermal interface material to fill different mean gap widths:

TABLE 2B

| | Thermal Impedance | Effective Thermal |
|---|---|---|
| Gap (μm) | (° C.-cm²/W) | Conductivity (W/m*K) |
| 212 | 0.393 | 5.41 |
| 112 | 0.209 | 5.40 |
| 87 | 0.158 | 5.50 |
| 25 | 0.029 | 8.66 |

### Example 3

The following Table 3A describes the composition of the thermal interface material:

TABLE 3A

| | 88 vol % metal | | |
|---|---|---|---|
| | filler | | |
| Thermal Interface | Formulation | Concentration | |
| Material | (phr) | (wt %) | Mass (g) |
| Silicone Polymer | 90 | 1.8 | 2.15 |
| Trimethoxy(octyl)silane | 10 | 0.2 | 0.24 |
| Particulated Metal Filler | 4914 | 98.0 | 117.61 |

The matrix material was formed from a silicone polymer having a viscosity of 500 cP at 25° C. The particulated metal filler was an alloy of 66% by weight gallium, 20.5% by weight indium, and 13.5% by weight tin. The particulated metal filler had a mean particle size of 60 μm and a melting point temperature of 10.5° C. The trimethoxy (octyl) silane was used as a surface modifying agent for providing hydrophobicity to the particulated metal filler.

The following Table 3B sets forth thermal impedance and effective thermal conductivity values of a heat transfer assembly using the thermal interface material to fill different mean gap widths:

TABLE 3B

| | Thermal Impedance | Effective Thermal |
|---|---|---|
| Gap (μm) | (° C.-cm²/W) | Conductivity (W/m*K) |
| 224 | 0.325 | 6.91 |
| 107 | 0.217 | 4.92 |
| 64 | 0.123 | 5.23 |
| 32 | 0.021 | 15.03 |

The thermal testing in each of Examples 1-3 demonstrates acceptable thermal conductivity performance across all tested mean gap widths. However, the testing further demonstrates significantly reduced thermal impedance (and increased thermal conductivity) with reduced mean gap width, with the lowest thermal impedance values exhibited in heat transfer assemblies employing thermal interface materials with particulated metal filler having a mean particle size at least as great as the mean gap width, and particularly a mean particle size that is at least 150%-200% of the mean gap width.

That which is claimed is:

1. A heat transfer assembly, comprising:
a first surface;
a second surface spaced from the first surface by a gap having a mean gap width; and
a thermal interface material disposed in the gap and in contact with the first and second surfaces, the thermal interface material including a matrix material and a particulated metal filler dispersed in the matrix material, the particulated metal filler having a melting point temperature of between 0° C. and 100° C. and a mean particle size that is equal to or larger than the mean gap width, wherein the mean gap width is less than 500 μm.

2. The heat transfer assembly as in claim 1, including 40-95% by volume of the particulated metal filler in the thermal interface material.

3. The heat transfer assembly as in claim 1 wherein the particulated metal filler is an alloy of one or more of gallium, indium, bismuth, tin, and zinc.

4. The heat transfer assembly as in claim 3 wherein the particulated metal filler is an alloy of between 50-75% by weight gallium, 10-30% by weight indium, and 5-20% by weight tin.

5. The heat transfer assembly as in claim 4 wherein the particulated metal filler has a melting point temperature of between 0° C. and 20° C.

6. The heat transfer assembly as in claim 1, including a hydrophobic surface active agent chemically bonded to a surface of the particulated metal filler.

7. The heat transfer assembly as in claim 6 wherein the hydrophobic surface active agent includes an alkyl-tri-alkoxy silane.

1. eat transfer assembly as in claim 1 wherein a weight ratio of the particulated metal filler to the matrix material is between 20:1 and 60:1.

9. The heat transfer assembly as in claim 8 wherein the weight ratio of the particulated metal filler to the matrix material is between 30:1 and 55:1.

10. The heat transfer assembly as in claim 1 wherein the matrix material includes a thermoplastic elastomer and is formed from a fluid resin having a viscosity of between 200-1,000 cP at 25° C.

11. The heat transfer assembly as in claim 1 wherein the mean particle size of the particulated metal filler is at least 150% of the mean gap width.

12. The heat transfer assembly as in claim 11 wherein the mean gap width is less than 200 μm.

13. The heat transfer assembly as in claim 1, including a mesh body disposed in the gap.

14. The heat transfer assembly as in claim 13 wherein the mesh body is embedded in the thermal interface material.

15. The heat transfer assembly as in claim 13 wherein the mesh body comprises a metal or graphite.

16. The heat transfer assembly as in claim 1 wherein the first surface is associated with a heat generating device, and the second surface is associated with a heat dissipater, wherein the heat dissipater is a heat sink or a heat spreader.

17. A method for forming a heat transfer assembly defining a gap having a mean gap width separating a first surface from a second surface, the method comprising:
(a) Providing a thermal interface material comprising:
(i) a matrix material;
(ii) a particulated metal filler dispersed in the polymer matrix, the particulated metal filler having a melting point temperature of between 0° C. and 100° C., and a solid phase mean particle size that is equal to or greater than the mean gap width; and
(b) applying the thermal interface material to at least one of the first and second surfaces.

18. The method as in claim 17, including contacting the thermal interface material to both of the first and second surfaces and arranging the first and second surfaces to be separated by the gap.

19. The method as in claim 18 wherein the first surface is associated with a heat generating device.

20. The method as in claim 19 wherein the second surface is associated with a heat dissipater.
